(19) United States
(12) Patent Application Publication
(10) Pub. No.: US 2007/0185242 A1
(43) Pub. Date: Aug. 9, 2007

(54) LOW TEMPERATURE CURING INK FOR PRINTING OXIDE COATING AND PROCESS THE SAME

(76) Inventor: Yuhong Huang, West Hills, CA (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/557,586

(22) Filed: Nov. 8, 2006

Related U.S. Application Data
(60) Provisional application No. 60/734,883, filed on Nov. 8, 2005.

(51) Int. Cl. H01L 21/316; C08G 59/50

(52) U.S. Cl. 523/429; 106/287.18; 106/287.19

(57) ABSTRACT

A composition suitable for application as an ink, and a method of producing a composition for forming a porous oxide-based coating on a substrate including: 1) fabricating reactive nano particles; 2) fabricating active submicron powder with a reactive surface; and 3) mixing reactive powders with organic vehicle to form an ink. A viscosity of the ink can be adjusted by adding high boiling point solvents. An ink can be printed via a variety of printing processes to form a coating. Upon thermal cure an oxide-based compound coating is formed with adhesion to a substrate.

### CROSS-REFERENCE TO RELATED APPLICATION

This application claims the benefit of the earlier filing date of co-pending U.S. Provisional Patent Application No. 60/734,883, filed Nov. 8, 2005.

### FIELD

The present invention generally relates to the field of fabricating oxide-based compound ink or paste for printing processes, including providing a porous oxide-based compound coating. More particularly, the present invention relates to a low temperature processing porous oxide-based compound coating. The present invention further relates to fabrication of an electrode coating on a conductive foil for use in a capacitor and the like.

### BACKGROUND

Printing inks (or also called paste) are mixtures of three main types of ingredients: active ingredients, vehicles and additives. Active ingredients can be pigments, phosphors, oxides and so on dependent on the application.

There are five main printing processes, and inks are typically designed for a specific process. Lithography and letterpress are collectively known as the ‘paste ink’ processes and use inks that are essentially non-volatile at normal temperatures. Flexography and gravure are known as the ‘liquid ink’ processes and are based upon volatile solvents that evaporate readily at room temperatures. Screen printing uses inks that fall between the other two groups. Pad printing and ink-jet printing are other commonly used printing techniques.

Choice of the vehicle (solvent with resins) for a printing ink depends on the printing process, how the ink will be dried, and the substrate on which the image is to be printed. Additives in inks includes driers, waxes and plasticizers.

U.S. Pat. Nos. 6,719,422; 5,242,623; 5,089,172 and 5,096,619, release thick oxide film paste composition. The active ingredient composes oxides powder and glassy phase. By firing printed coating to at least 800° C., organic vehicle is burned out and oxide coating is densified due to melted glassy phase bonding.

U.S. Pat. Nos. 5,132,045 and 5,277,840, disclose a phosphor paste composition, which contains organic binder and phosphor with a particle size on the order of 1-9 micron. The surface of the phosphor particles is coated with terbium. By firing to 400° C., pinhole-free smooth coating can be formed.

U.S. Pat. No. 5,071,794, provides for a porous dielectric composition comprising crystallized glass and non-crystallized glass and organic binder vehicle. By firing to at least 800° C., a porous thick film is formed with porosity ranging from 2% to 50%.

U.S. Pat. No. 6,224,985 discloses a deposition process for coating a substrate with an ultrasonically generated aerosol spray of a pseudocapacitive material, or a precursor thereof, contacted to a substrate heated to a temperature to instantaneously solidify the pseudocapacitive material or convert the precursor to a solidified pseudocapacitive metal compound. The substrate is heated to a temperature of about 100° C. to about 500° C., preferably about 350° C. to instantaneously convert the precursor to an oxide coating.

U.S. Pat. No. 6,455,108 describes a pseudocapacitive material contacted to a substrate by a thermal spraying process. The substrate is heated to a temperature, preferably about 400° C. to instantaneously fuse the pseudocapacitive material thereto. Upon completion of fusing, the heated and coated substrate is allowed to slowly cool to ambient temperature.

The prior art describes various methods of contacting the substrate with the semiconductive or pseudocapacitive solution, or precursor thereof. Commonly used techniques include dipping, solution spraying and thermal spraying of the pseudocapacitive material onto the substrate.

Even though electrochemical capacitors provide much higher energy storage densities than conventional capacitors, there is a need to further increase the energy storage capacity of such devices. There is also a need to develop a high throughput manufacture process as well as a process, which can utilize raw materials more efficiently especially for precious metal based compounds, such as ruthenium oxide.

### SUMMARY

In one embodiment of the invention, a printable ink composition comprising finely divided particles of functional solids as active ingredients dispersed in an organic vehicle is disclosed. Two types of active ingredients may be used. One is a surface activated submicrometer sized powder. Another is the mixture of two types of particles or powders. A first sub-micrometer sized powder is chosen as a building block for a porous coating. The surface of the sub-micrometer sized powder is activated using, for example, a mechanochemical milling process. Small amounts of a nano-sized ruthenium hydroxide second powder is introduced to further enhance the capability of forming chemical bonding at low temperature. A suitable polymer capable of burning off in air at a sufficiently low temperature is used as an organic vehicle to provide printability to the powder combination.

The ink, a mixture of active ingredient and organic vehicle, is printable. The organic in the ink formulation can be burned out at a sufficiently low temperature (e.g., less than 400° C.). After thermal treatment at low temperature, a porous oxide based inorganic compound coating is formed.

The printable ink may be used to form capacitor electrodes that can be manufactured with repeatably controllable morphology, in turn benefiting repeatably increased effective surface areas.

### BRIEF DESCRIPTION OF THE DRAWINGS

FIG. 1 XRD of printed coating cured at 350° C. Coating contains crystalline phase of ruthenium oxide and small amount of ruthenium metal.

FIG. 2 SEM of ruthenium oxide coating on titanium printed using the invented ink and thermally cured at 350° C.

FIG. 3 Thermal decomposition of an ink composition analyzed by using TGA.

### DETAILED DESCRIPTION

A method of producing an ink for low temperature forming of a porous oxide-based coating on a substrate is disclosed. The method is useful in one embodiment for forming a porous oxide coating on a metal substrate. In one embodiment, the method includes, 1) fabricating an active ingredient; 2) mixing the active ingredient with an organic vehicle to form an ink. A suitable active ingredient can be either an active submicron powder with a reactive surface or a mixture of a reactive nano powder and an active submicron powder with a reactive surface. A viscosity of the ink can be adjusted by adding high boiling point solvent. The ink can be printed via a variety of printing processes for forming a coating. Upon thermal curing at temperature on the order of, for example, 350° C., a porous oxide-based compound coating is formed with good adhesion to a substrate.

Metal hydroxide nano particles are fabricated by reaction of a metal chloride with sodium hydroxide in water. The byproduct of the reaction is sodium chloride. Sodium chloride will be separated through a subsequent washing process. The metal hydroxide nano powder is then dried at temperature of 80 to 100° C. for 10 to 24 hours.

In order to form a porous structure of the coating, a submicron sized metal oxide powder is used as building block. Suitable metal oxides include oxides of ruthenium, molybdenum, tungsten, tantalum, cobalt, manganese, nickel, iridium, iron, titanium, zirconium, hafnium, rhodium, vanadium, osmium, palladium, platinum, niobium and mixture thereof. A surface is activated by a mechanochemical milling process in the presence of the oxide powder, alcohol and metal balls as both milling medium and catalyst to promote chemical reaction on the surface of oxide powder.

A suitable organic vehicle capable of burning off in air at a sufficiently low temperature is commercially available. For example, a suitable organic vehicle is a terpineol/polymer-based material commercially available under the name CERDEC 1562 from Cerdec Corporation Drakenfeld Products, through other organic vehicles could be used.

Ink is formulated by mixing the active ingredient and the organic vehicle, and placing the mixture in an oven at 80 to 120° C. for 1 to 6 hours. The ink is then mechanically blended using, for example, three-roll mill to blend. The viscosity of the ink is adjusted by adding additional high boiling point solvent, such as terpineol. The solid loading (oxide based compound powder percentage) is in the range of 15 to 70 wt %. The viscosity of the ink is adjusted to the range of 5,000 to 15,000 CentiPoises (cp).

The formulated ink can be printed onto substrate via a number of printing processes, including but not limited to screen printing, pad printing and ink-jet printing. By sintering to the temperature higher than 250° C., preferably 350° C., the organic vehicle in the ink can be burned out and the porous oxide coating can then be formed. For application in forming a capacitor, the substrates are often metal current collectors made from titanium, tantalum, their alloys or other conductive materials.

The oxide electrode coating on a current collector can then be constructed into electrochemical capacitor by adding electrolyte, separator and sealing. The oxide electrode coating can also be used as cathode for hybrid capacitors. The anode of capacitor can be tantalum electrolyte capacitor or ceramic dielectric capacitor. Hybrid capacitors can typically deliver much high pulse power, which is essential for applications, for example, in implantable defibrillators.

### EXAMPLE 1

In one embodiment, the desired ink for fabrication of a porous coating on a metal substrate via high throughput printing process for an electrode of an electrochemical capacitance should possess: 1) Good printability; 2) Thermal curing of a temperature lower than 400° C.; 3) good adhesion to the current collector to provide low resistance and high power density; 4) result in a porous thick film for obtaining high capacitance and high energy storage; and 5) can be easily scale-up to high throughput production.

In one embodiment, activated ruthenium oxide powder may be used to form porous coating. The porous coating is capable of being formed at low temperatures (e.g., less than 400° C.) in order to be integrated with devices. The porous coating has good adhesion to the current collector and to each other to guarantee good conductivity.

Two types of particles are present in the ink composition. The submicrometer sized oxide (e.g., ruthenium oxide) powder is chosen as building block for porous coating. The surface of the powder is activated using mechanochemical milling process. Small amount of a nano-sized powder (e.g., ruthenium hydroxide) is introduced to further enhance the capability of forming chemical bonding at low temperature.

Ruthenium hydroxide can be synthesized by reaction of ruthenium chloride with sodium hydroxide in water. The byproduct of the reaction is sodium chloride. Sodium chloride will be separated through washing process. The ruthenium hydroxode nano powder is then dried at temperature of 80 to 100° C. for 10 to 24 hours.

In one embodiment, to form a porous structure of the coating, 0.5 um ruthenium oxide powder from J&J Materials, Inc. is used. Ruthenium oxide powder surface is activated by mechanochemical milling process in present of oxide powder, alcohol and metal ball as both milling medium and catalyst to promote chemical reaction on the surface of the ruthenium oxide powder.

Ink is formulated by mixing active ruthenium oxide powder, ruthenium hydroxide nano particles and an organic vehicle, and placed in oven at 80 to 120° C. for 1 to 6 hours. Ink is then mechanically blended or using three-roll mill to blend. The viscosity of the ink is adjusted by adding additional terpineol. The solid loading is in the range of 15 to 70 wt %. The viscosity of the ink is adjusted to the range of 5,000 to 15,000 cp.

In one embodiment, the ink may be used to form a ruthenium oxide electrode of a capacitor (supercapacitor or electrochemical capacitor). The ink may be printed on to a current collector. Suitable material for a current collector includes, but is not limited to, tantalum, titanium, nickel, molybdenum, niobium, cobalt, stainless steel, tungsten, platinum, palladium, gold, silver, copper, chromium, vanadium, aluminum, zirconium hafnium, zinc, iron and mixture thereof. Suitable printing techniques include, but are not limited to pad-printing and screen printing techniques. A thickness of the printed ink coating can vary depending on application from very thin (e.g., on the order of 0.1 microns) to relatively thick (e.g., 10 micron or more). Following printing, the ink may be cured at a temperature on the order of 350° C. to 400° C.

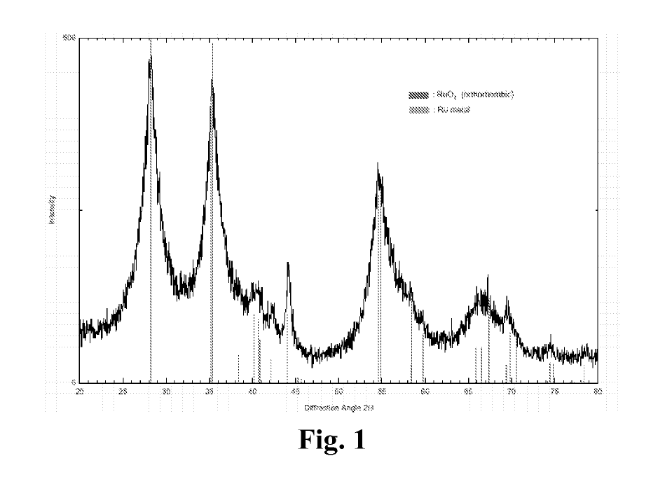

FIG. 1 shows the X-ray diffraction spectrum of ruthenium oxide coating, which is printed using the said invented ink and cured at 350° C. The coating possesses ruthenium oxide crystalline phase and small amount of ruthenium metal phase.

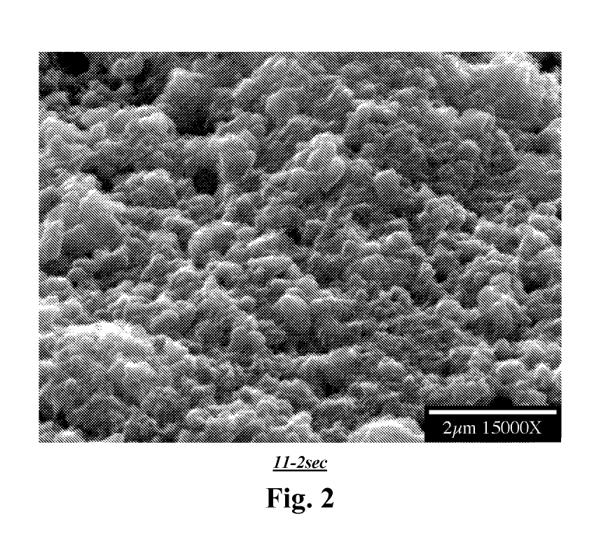

FIG. 2 is a SEM photo of ruthenium oxide coating, which is printed using the said invented ink and cured at 350° C. The coating is porous. The articles are sintered between each other form a strong bonding.

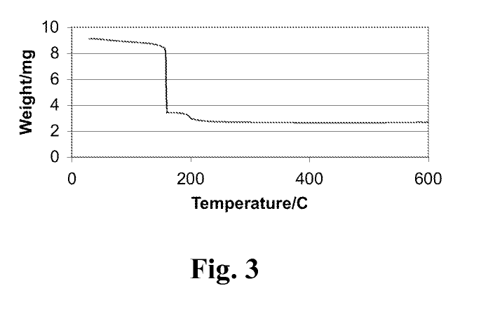

FIG. 3 is a typical thermal decomposition of said invented ink. The organic vehicle can be burned out at the temperature below the 350° C.

Due to the unique porous structure of coating and chemical bonding between particles, the ruthenium oxide coating electrode has much higher specific capacitance compared previous art disclosed methods. A specific capacitance of 200 to 350 F/g was obtained from a coating electrode printed using the said invented ink and cured at 350° C.

### EXAMPLE 2

Fabrication of ruthenium hydroxide powder:

Step 1. Dissolve 380 g of ruthenium chloride hydrate in 5 L de-ionized water in a 22 L flask and 220 g of NaOH in 1 L de-ionized water in a 2L flask under stirring.

Step 2. Upon complete dissolution, add NaOH aqueous solution into ruthenium chloride solution slowly at an rate of 6 ml/min.

Step 3. Check pH after the completion of NaOH addition. Adjusting pH to larger than 7.0. The solution is allowed to settle for overnight for sediment.

Step 4. Decant clear top solution out of the reactor, followed by transfer the bottom solution to centrifuge boxes.

Step 5. Wash the filter cake 5 times with deionized water. Dislodge the filter cake and place it in oven. Drying at 85° C. for 18 hours.

### EXAMPLE 3

Active ruthenium oxide powder process:

Mixing 720 g of ruthenium oxide hydrate powder together with 1670 g milling balls and 1000 g ethyl alcohol in a 2 L bottle. Place the charged bottle onto ball milling machine and milling for 4 days.

Separate paste with milling balls and drying the paste in the oven at 60° C. for 16 hours.

### EXAMPLE 4

Add 360 g of activated RuO₂/Ru(OH)₃ powder and 840 g of organic vehicle in a container of organic kettle. The mixing was conducted at the temperature of 85° C. for 3 hours with mechanic stirring using attached shaft of organic kettle. The ink was then allowed to cool down and charged into a bottle.

What is claimed is:

1. A method comprising:
fabricating nanosized hydroxide metal particles;
fabricating a surface reactive oxide powder; and
mixing the oxide powder and hydroxide metal particles with an organic vehicle to form an ink suitable for printing a porous coating.

2. The method of claim 1, wherein the ink can be cured at temperature below 400° C.

3. The method of claim 1, wherein fabricating hydroxide nanoparticles comprises reacting metal chloride with sodium hydroxide in water at room temperature.

4. The method of claim 3, wherein reacting comprises a reaction time of 3 to 10 hours.

5. The method of claim 3, wherein reacting produces a byproduct of sodium chloride and fabricating hydroxide nanoparticles further comprises separating sodium chloride through a washing process.

6. The method of claim 5, wherein the washing process comprises centrifuging to precipitate metal particles.

7. The method of claim 6, further comprising drying the metal particles at 80 to 120° C. for five to 48 hours.

8. The method of claim 1, wherein fabricating surface reactive oxide powder comprises a ball milling process wherein an oxide powder, alcohol and metal balls are mixed in a mill.

9. The method of claim 8, wherein the oxide powder comprises a particle size of submicron.

10. The method of claim 8, wherein the alcohol comprises a mixture of several kinds of alcohol.

11. The method of claim 8, wherein the metal balls comprise stainless steel balls.

12. The method of claim 8, wherein a milling time is about three to six days.

13. The method of claim 1, wherein the organic vehicle is capable of burning off in air at a sufficiently low temperature.

14. The method of claim 1, wherein a solid content of oxide powder and hydroxide particles is about 15 to 70 percent.

15. The method of claim 1, wherein the metal oxide powder comprises a metal selected from the group consisting of ruthenium, molybdenum, tungsten, tantalum, cobalt, manganese, nickel, iridium, iron, titanium, zirconium, hafnium, rhodium, vanadium, osmium, palladium, platinum, niobium and mixture thereof.

16. The method of claim 1, wherein the ink comprises ruthenium.

17. The method of claim 1, wherein the ink comprises an element selected from group consisting of tantalum, titanium, nickel, molybdenum, niobium, cobalt, stainless steel, tungsten, platinum, palladium, gold, silver, copper, chromium, vanadium, aluminum, zirconium hafnium, zinc, iron and mixtures thereof.

18. A printable ink composition comprising:
a nanosized hydroxide metal particles;
a surface reactive oxide powder; and
an organic vehicle to render the composition suitable for printing.
